(19) United States
(12) Patent Application Publication
(10) Pub. No.: US 2004/0000698 A1
(43) Pub. Date: Jan. 1, 2004

(54) CMOS MODULE FOR USED IN AN OPTICAL MOUSE

(76) Inventor: Shu-Fen Chen, Taichung (TW)

Correspondence Address: SHU-FEN CHEN, P.O. Box 2103, Taichung, TW

(21) Appl. No.: 10/184,885

(22) Filed: Jul. 1, 2002

(51) Int. Cl. H01L 31/12

(52) U.S. Cl. 257/433

(57) ABSTRACT

A CMOS module with a light source. A CMOS image pickup unit and a light source are together packaged in the CMOS module. The light source is adjacent to one side of the CMOS image pickup unit. Light beam is projected from the light source onto an image pickup range of the CMOS image pickup unit.

### BACKGROUND OF THE INVENTION

A present invention is related to a CMOS module with a light source, in which a CMOS image pickup unit and a light source are together packaged.

A Digital image technique has been widely applied to those devices for judging, calculating and locating moving object.

FIG. 6 shows a conventional optical mouse employing the digital image technique. A CMOS module 71 is disposed in the optical mouse 7. The CMOS module 71 is disposed on a circuit board 72. Multiple electronic elements 73 are arranged on the circuit board 72 for normal operation of the optical mouse 7. A CMOS image pickup unit 74 is disposed in the CMOS module 71. In addition, an LED light source 75 is disposed on the circuit board 71 beside the CMOS module 71. A lens combination 8 is disposed under the CMOS module 71 and the LED light source 75. The lens combination 8 includes an image magnifying lens 81 and a prism 82.

By means of the prism 82, a light beam is projected from the LED light source 75 onto an image pickup range of the CMOS image pickup unit 74. Accordingly, the CMOS image pickup unit 74 can pick up the reflected image of the light beam projected onto the image pickup range. The CMOS module 71 can calculate the moving distance and direction of the optical mouse 7.

Referring to FIG. 7, the CMOS image pickup unit 74 is solely packaged in the CMOS module 71. The LED light source 75 and the lens combination 8 are additionally mounted on the circuit board 71. Therefore, the area of the circuit board 71 is enlarged to occupy more internal space of the optical mouse 7. Under such circumstance, the volume of the optical mouse 7 can be hardly minified. Therefore, such CMOS module 71 cannot be applied to a small-size device.

Moreover, the LED light source 75 must be additionally mounted so that the assembling procedure is complicated and the manufacturing cost is increased.

Furthermore, the LED light source 75 is disposed on one side of the CMOS module 71 to transversely project light beam. The light beam is turned from transverse direction into an oblique downward direction by the prism 82. Therefore, the path of the light beam is turned many times and elongated. As a result, the illumination is declined.

### SUMMARY OF THE INVENTION

It is therefore a primary object of the present invention to provide a CMOS module with light source. A CMOS image pickup unit and a light source are integrally together packaged in the CMOS module. Therefore, the volume of the CMOS module is reduced and the CMOS module can be applied to a small-size device.

It is a further object of the present invention to provide the above CMOS module in which the CMOS image pickup unit and the light source are together packaged in the CMOS module 1. Therefore, the light source is adjacent to the CMOS image pickup unit to shorten the path of the light beam and achieve a brighter illumination.

It is still a further object of the present invention to provide the above CMOS module in which with a shortened path of the light beam emitted from the light source, a low illumination light source such as an SMT-type LED lamp can be used to achieve sufficient illumination within the image pickup range of the CMOS image pickup unit. Therefore, the power for the light source can be saved.

The present invention can be best understood through the following description and accompanying drawings wherein:

### BRIEF DESCRIPTION OF THE DRAWINGS

FIG. 1 is a view showing that the CMOS module of the present invention is mounted in an optical mouse;

FIG. 2 is a bottom view of the present invention;

FIG. 3 shows that the light beam is projected from the light source onto the image pickup range of the CMOS image pickup unit of the present invention;

FIG. 4 shows a second embodiment of the present invention;

FIG. 5 shows a third embodiment of the present invention;

FIG. 6 is a view showing that a conventional CMOS module is mounted in an optical mouse; and

FIG. 7 is a bottom view of the conventional CMOS module.

### DETAILED DESCRIPTION OF THE PREFERRED EMBODIMENTS

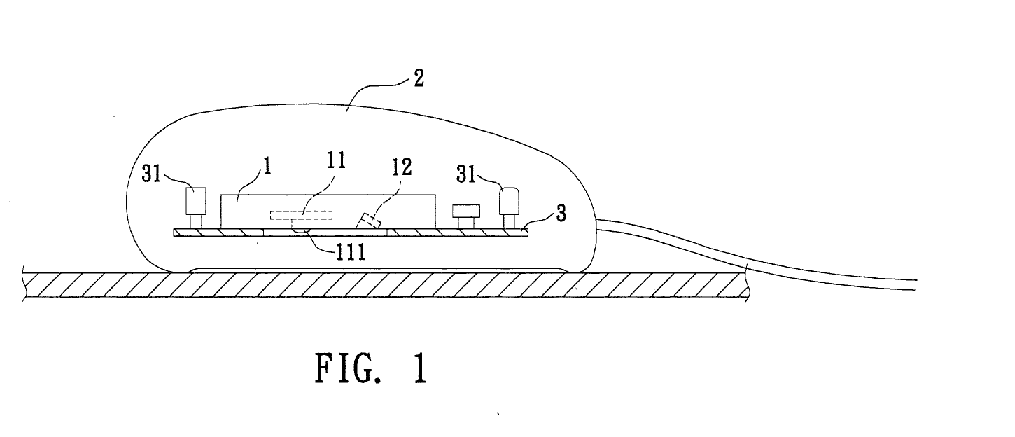

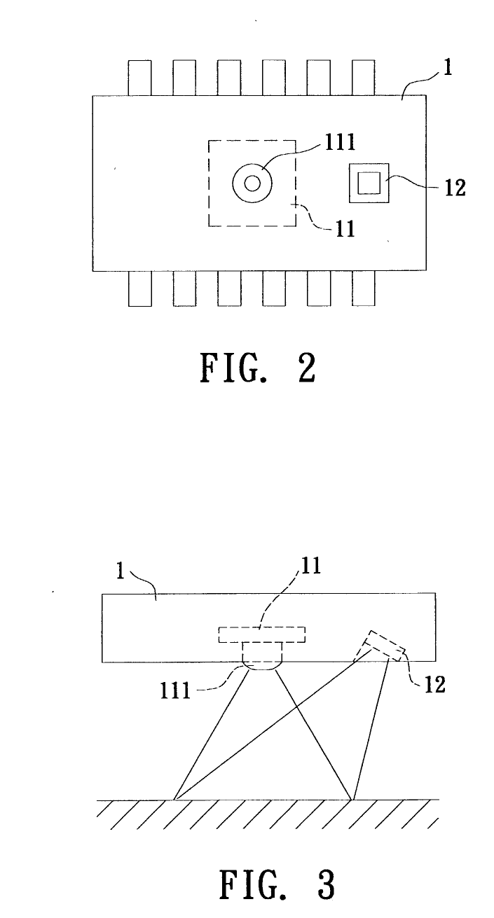

Please refer to FIGS. 1 to 3. The present invention is related to a CMOS module with a light source. In order to facilitate description of the present invention, an optical mouse to which the present invention is applied is exemplified herein. The CMOS module 1 is disposed on a circuit board 3 inside the optical mouse 2. Multiple electronic elements 31 are arranged on the circuit board 3 for normal operation of the optical mouse 2. A CMOS image pickup unit 11 and a light source 12 are together packaged in the CMOS module 1. The CMOS image pickup unit 11 has a viewing window 111. In this embodiment, the light source 12 is an SMT-type LED lamp. The light source 12 is adjacent to one side of the CMOS image pickup unit 11 and inclined by a certain angle. Accordingly, the light beam is projected from the light source 12 onto an image pickup range of the viewing window 111 of the CMOS image pickup unit 11.

Accordingly, the CMOS image pickup unit 11 can pick up the reflected image of the light beam projected onto the image pickup range. Furthermore, the CMOS module 1 can calculate the moving distance and direction of the optical mouse 2.

The CMOS image pickup unit 11 and the light source 12 are together packaged in the CMOS module 1. Therefore, the total volume of the CMOS module 1 is minified and thus the CMOS module 1 can be applied to small-size device.

Moreover, the CMOS image pickup unit 11 and the light source 12 are together packaged in the CMOS module 1. Therefore, the number of the components is reduced and the assembling procedure is simplified so that the manufacturing cost is lowered.

In addition, the CMOS image pickup unit 11 and the light source 12 are together packaged in the CMOS module 1. Therefore, the light source 12 can be adjacent to the CMOS image pickup unit 11 to shorten the path of the light beam and achieve a brighter illumination.

In addition, with the shortened path of the light beam emitted from the light source 12, a low illumination light source such as an SMT-type LED lamp can be used to achieve sufficient illumination within the image pickup range of the viewing window 111 of the CMOS image pickup unit 11. Therefore, the power for the light source 12 can be saved.

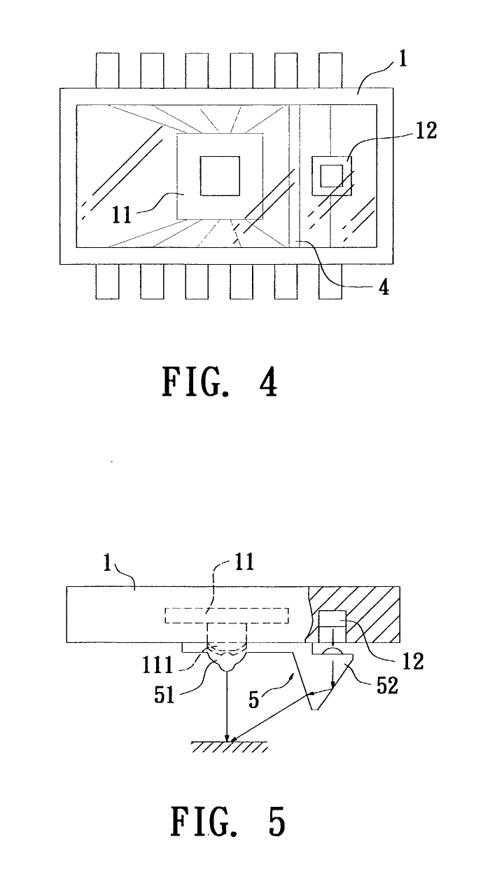

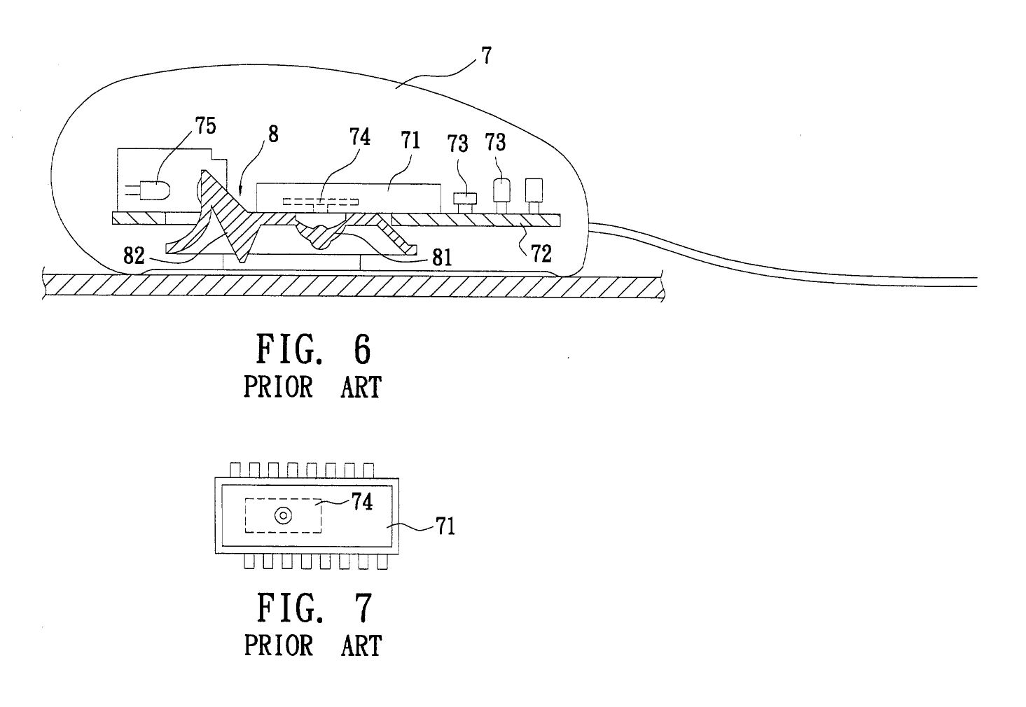

FIG. 4 shows a second embodiment of the present invention, in which the CMOS module 1 is packaged with a transparent lid. The CMOS image pickup unit 11 and the light source 12 are positioned in the same space. In order to prevent the light beam from the light source 12 from directly interfering with the CMOS image pickup unit 11, an insulation is disposed between the CMOS image pickup unit 11 and the light source 12. In this embodiment, the insulation is an insulation wall 4 for interrupting the sidelight of the light source 12 so as to avoid interference with the CMOS image pickup unit 11.

FIG. 5 shows a third embodiment of the present invention, in which both the CMOS image pickup unit 11 and the light source 12 in the CMOS module 1 are directed downward. A lens combination 5 is disposed under the viewing window 111 and the light source 12. The lens combination 5 includes an image magnifying lens 51 and a prism 52. The image magnifying lens 51 is opposite to the viewing window 111, while the prism 52 is opposite to the light source 12. By means of the image magnifying lens 51, the viewing window 111 can pick up better image. The prism 52 focuses the light beam from the light source 12 to the image pickup range of the CMOS image pickup unit 11.

The above embodiments are only used to illustrate the present invention, not intended to limit the scope thereof. Many modifications of the above embodiments can be made without departing from the spirit of the present invention.

What is claimed is:

1. A CMOS module with a light source, a CMOS image pickup unit and at least one light source being together packaged in the CMOS module, the light source being adjacent to one side of the CMOS image pickup unit, light beam being projected from the light source onto an image pickup range of the CMOS image pickup unit.

2. The CMOS module with light source as claimed in claim 1, wherein the CMOS image pickup unit has a viewing window, a lens combination being disposed under the viewing window and the light source, the lens combination including an image magnifying lens and a prism, the image magnifying lens being opposite to the viewing window, while the prism being opposite to the light source.
